(19) United States
(12) Patent Application Publication
(10) Pub. No.: US 2007/0107205 A1
(43) Pub. Date: May 17, 2007

(54) Device and method for linking microchip modules with antennas

(76) Inventors: Bernhard Mende, Dresden (DE); Sven Hochmann, Dresden (DE)

Correspondence Address: BLACK LOWE & GRAHAM, PLLC, 701 FIFTH AVENUE, SUITE 4800, SEATTLE, WA, 98104, US

(21) Appl. No.: 10/555,808

(22) PCT Filed: May 6, 2004
(86) PCT No.: PCT/EP04/04798

§ 371 Date: Jan. 16, 2007

(30) Foreign Application Priority Data
May 8, 2003 (DE) 103 20 843.7

(51) Int. Cl. H01Q 17/00; H05K 3/30

(52) U.S. Cl. 29/601; 29/832; 29/740; 29/739

(57) ABSTRACT

An apparatus and a method for joining microchip modules to antennas (18) which are arranged on at least one first support (1) for producing transponders. in particular smart labels. for transferring the microchip modules (12) from at least one second support (5, 5a, 5b) to predefined locations on the first support (1). wherein the two supports can be moved in steps or continuously one above the other, wherein the supports which can be moved one above the other are arranged parallel to one another at a predefined section, and arranged between the supports is a turning head device (9) for transferring individual microchip modules (12) from the second to the first support (1; 5, 5a, 5b) by way of a rotational movement (11), which turning head device can rotate about an axis that runs in the direction of the support width.

The invention relates to an apparatus for joining microchip modules to antennas which are arranged on at least one first support for producing transponders, in particular smart labels, for transferring the microchip modules from at least one second support to predefined locations on the first support, according to the preamble of claim 1. The invention furthermore relates to a method for joining microchip modules to antennas which are arranged on at least one first support for producing transponders, in particular smart labels, according to the preamble of claim 11.

EP 1 043 925 A2 discloses an apparatus and a method for automatically transferring a plurality of identical electronic components to a plurality of circuits which are arranged on a substrate strip. The substrate strip is unwound from a roll and is connected via a main roll to an antenna transfer roll, in order to apply individual antennas one by one to the substrate strip. Via another roll which is in contact with the main roll, the individual electronic components are then applied one by one to the substrate strip, in order to obtain a plurality of transponders.

Firstly, such an apparatus requires the two transfer steps of applying the antennas and applying the electronic components to the substrate strip. Secondly, the transfer of the electronic components to the substrate takes place in an area in which the substrate strip rolling off the main roll comes close to the roll carrying the electronic components. In this case, the substrate strip and the electronic components are arranged so that they run over a circular surface at their point of contact on account of their arrangement on the roll surfaces. On account of this circular course, such designs require special devices for removing the components from the further roll, for transferring the components to the substrate strip and for joining the components to the substrate strip, and these devices are complicated in terms of their design and expensive to manufacture. Moreover, on account of the circular arrangement of the components arranged in a row and of the substrate strip, the operations of removing, transferring and joining the components can be carried out simultaneously only with additionally technically complicated designs.

DE 101 36 359 A1 discloses methods for joining microchip modules to antennas which are arranged on a first support strip for producing a transponder, in which the microchip modules, in order to be applied to the first support strip, are detached beforehand from a second support strip by passing the second support strip over a sharp edge. Such designs are not suitable for separating the microchip modules from the support strip by means of a cutting operation, which is often necessary for detaching certain types of microchip module from a composite.

Accordingly, it is an object of the present invention to provide an apparatus for joining microchip modules to antennas which are arranged on supports for producing transponders, in which simple and rapid transfer of the microchip modules from one support to the other support which already carries the antennas is possible even if a cutting operation has already been carried out to detach the microchip modules from their support, and which is of an easy and cost-effective design. Another object of the invention is to provide a method for joining the microchip modules to the antennas which are arranged on the supports.

This object is achieved in accordance with the features of claim 1 in respect of the apparatus and in accordance with the features of claim 11 in respect of the method.

One important aspect of the invention must be regarded as being the fact that, in an apparatus for joining microchip modules to antennas which are arranged on at least one first support for producing transponders, in particular smart labels, for transferring the microchip modules from at least one second support to predefined locations on the first support, the supports which can be moved in steps or continuously one above the other are preferably arranged parallel to one another at a predefined section, and arranged between the supports is a turning head device for transferring individual microchip modules from the second to the first support by way of a rotational movement. The turning head device can rotate through preferably 180° about an axis that runs in the direction of the support width, and by means of a vacuum-generating device exerts suction on the individual microchip modules, which have previously been detached from the second support, rotates through 180° and places said microchip modules on the first support lying therebelow. The microchip modules are then automatically pressed, preferably clinched, onto the first support by means of tools. Here, the joining operation and the separating operation may be carried out simultaneously, so that rapid and simple execution of the entire removal, transfer and joining process is possible.

By virtue of the use of a multisided turning head device, it may not be necessary for the turning head device to rotate back from the position for arranging the microchip modules on the first support to a position for removing and exerting suction on the microchip modules from the second support, since all the sides of the turning head device are designed to carry out each of these operations. By way of example, the turning head device may have four sides, so that in each case a rotational movement of just 90° is required. This in turn leads to a saving in terms of time during production.

The supports are advantageously designed as support strips, support sheets or support bands.

Advantageously, the first and/or second support strip may be designed as a two-lane strip or multi-lane strip in order to make it possible to simultaneously process a number of support strips and microchip modules which are arranged parallel to one another. This leads to a further saving in terms of time during production.

In order to precisely position the microchip modules (interposers) below a separating device for separating the microchip modules from the second support strip and above the turning head device, an index device is provided for guiding the second strip in the direction of advance and the lateral direction. The separating device may be designed as a cutting device, a punching device or a laser cutting device.

The support strips can in each case be unwound from a first roll and wound onto a second roll.

The assembly tools provided for the clinching operation are driven by means of an electromagnetic drive device for a striking device which is connected to the assembly tools, for moving the assembly tools in an accelerated manner in the direction of the microchip modules to be pressed on and for carrying out the pressing operation with a predefined depth of penetration of the microchip modules into the first support strip.

The striking device comprises a hammer-like element which is preferably driven electromagnetically or by means of a pretensioned spring.

The electromagnetic drive device is connected to an adjustment device which allows a movement of the drive device only once a defined and adjustable force has been overcome, so that the process parameters such as joining force and pulse can be varied.

According to one preferred embodiment, the magnet device is controlled in terms of its movement by means of a control device as a function of the current positions of the cutting device, the turning head device and the microchip modules to be pressed on, so that coordination of the movement sequences of these various devices is achieved in order to obtain a collision-free operating sequence and to reduce the time for each operating cycle.

In a method according to the invention for joining microchip modules to antennas which are arranged on at least one first support for producing transponders, in which the microchip modules are detached from at least one second support and are applied to predefined locations on the first support, wherein the two supports are moved one above the other, the supports which are moved one above the other run parallel to one another at a predefined section, wherein, by means of a rotatable turning head device which is arranged between the supports, individual microchip modules are transferred from the second to the first support. To do this, by means of a vacuum which is produced, the turning head device exerts suction on at least one microchip module which has previously been detached from the second support and, by virtue of a rotational movement of preferably 1800, places it at the predefined location on the first support lying therebelow.

A time-optimized operating process can be achieved if a separating operation, for example by cutting individual microchip modules out of the second support, and an assembly operation for pressing, in particular clinching, other individual microchip modules onto the first support take place simultaneously.

Further advantageous embodiments emerge from the dependent claims.

Advantages and expedient features can be found in the following description in conjunction with the drawing. In the drawing:

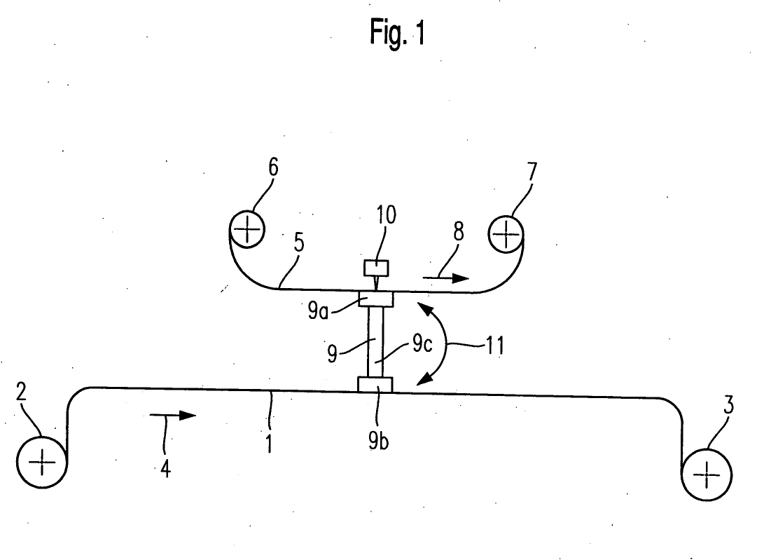

FIG. 1 shows a simplified schematic diagram of the basic principle of the apparatus according to the invention, in side view;

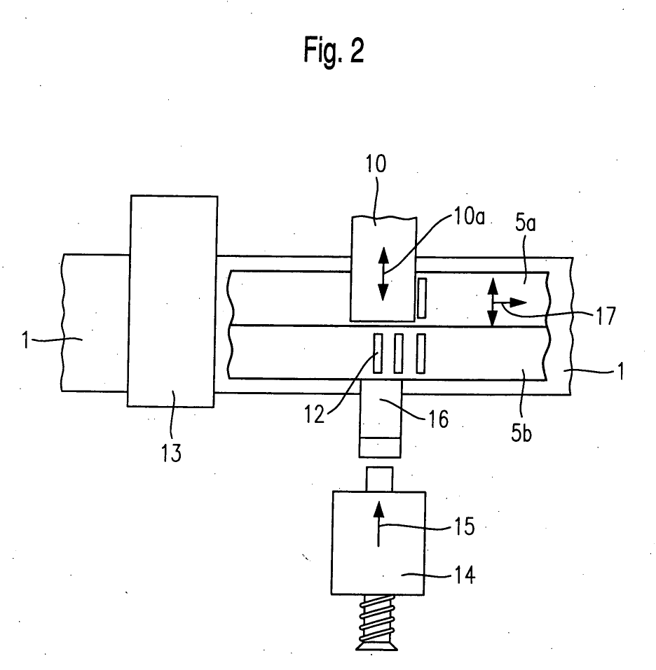

FIG. 2 shows a simplified schematic diagram of the basic principle of the apparatus according to the invention which is shown in FIG. 1, in plan view;

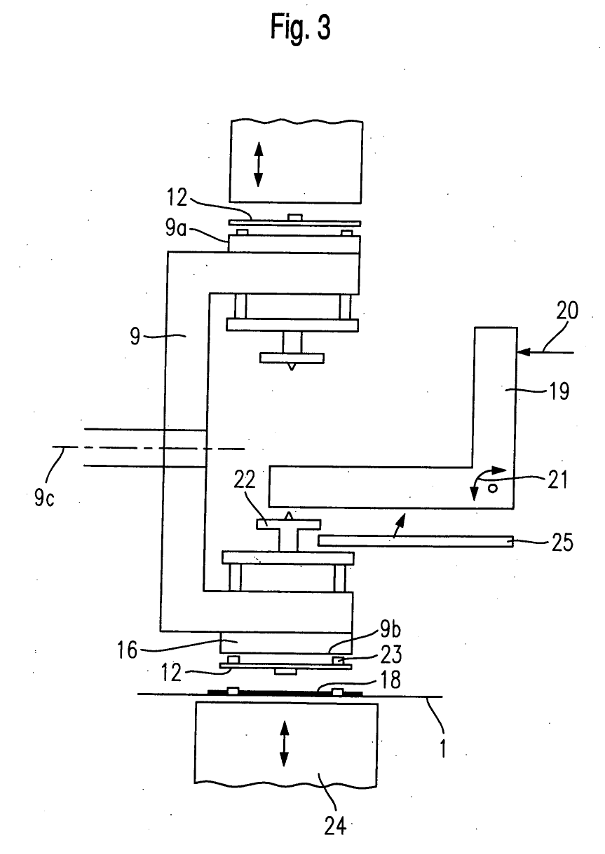

FIG. 3 shows a schematic side view of part of the apparatus according to the invention with a turning head device, according to one embodiment of the invention;

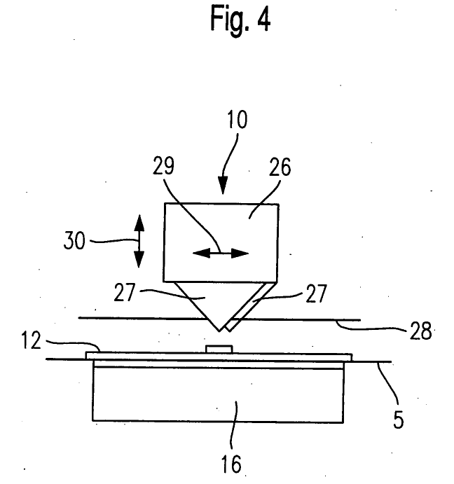

FIG. 4 shows a schematic side view of a cutting device according to one embodiment of the invention;

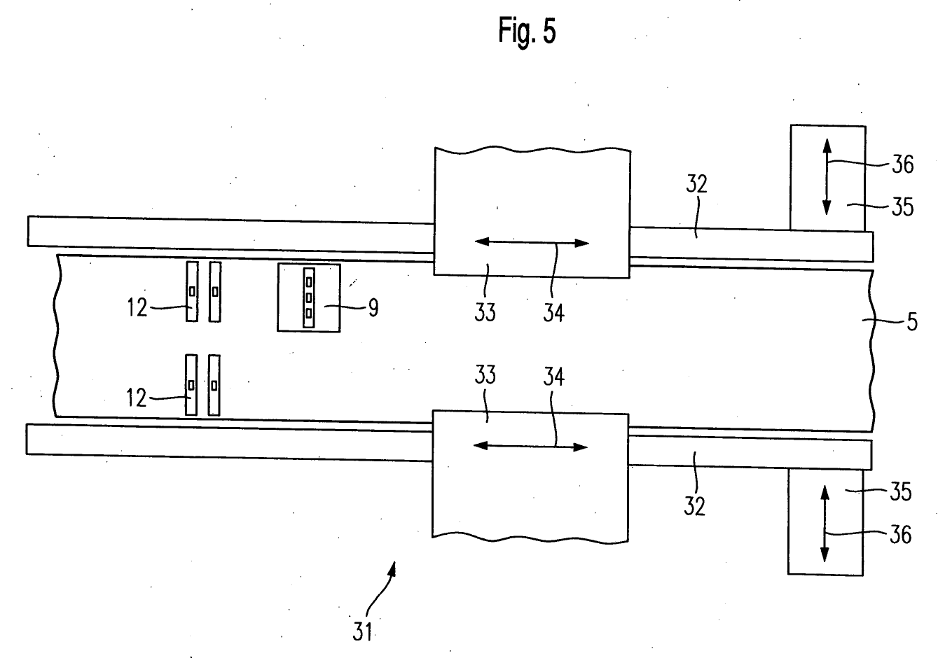

FIG. 5 shows a schematic diagram of an index guide device in plan view according to one embodiment of the invention, and

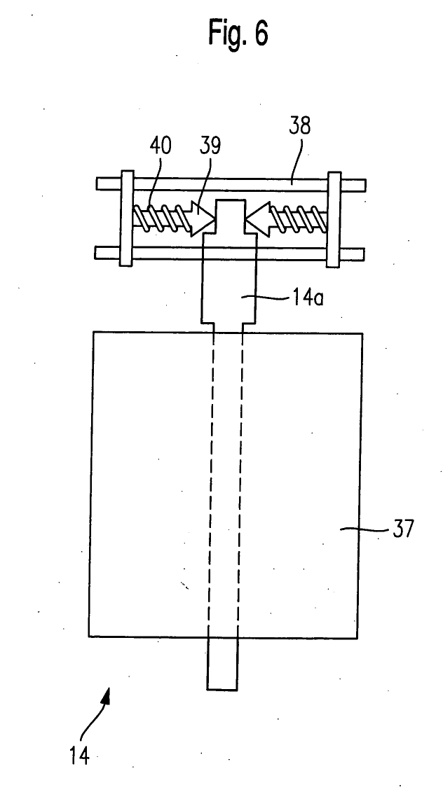

FIG. 6 shows a schematic plan view of an electromagnetic drive device according to one embodiment of the invention.

FIG. 1 shows, in a simplified schematic diagram, the basic principle of the apparatus according to the invention. In the apparatus, a first support strip 1 is unwound from a first roll 2 and wound onto a second roll 3. The running direction of the first support strip 1 is indicated by the arrow 4.

Arranged on top of the first support strip 1 are antennas (not shown here) which may be produced for example by electrodeposition.

Arranged in a second support strip 5 which runs parallel to the first support strip 1 and above the latter are microchip modules (not shown here). The second support strip 5 is unwound from a further first roll 6 and wound onto a further second roll 7. A running direction of the second support strip 5 is indicated by the arrow 8.

A turning head device 9 with an upper and a lower turning head side 9a and 9b is arranged between the two support strips 1 and 5 in such a way that it can be rotated about an axis 9c that runs perpendicular to the plane of the drawing, as indicated by the arrow 11. Both the turning head sides 9a, 9b are designed both for exerting suction on the microchip module which has been cut from the second support strip 5 by means of a cutting device 10 and also for placing the microchip module on the first support strip 1.

FIG. 2 shows, in a simplified schematic diagram, the basic principle of the apparatus in a plan view. As can be seen from this diagram, the second support strip 5 consists of two support strips 5a and 5b which are arranged next to one another and run parallel to one another. Arranged in the two support strips 5a and 5b are microchip modules 12 which can be cut from the second support strips 5a, 5b by means of the cutting device 10, which cutting device can carry out a displacement movement 10a in order to be positioned above the microchip modules.

A detection system 13 which is arranged at the start, and which is preferably designed as a vision system with a camera or sensor elements comprising evaluation elements, serves to detect and position the antennas arranged on the first support strip 1 and also to position them with respect to a drive device for assembly of the chip modules.

An electromagnetic drive device 14 serves together with a striking device to generate and transmit a pulse to the tools which are integrated in the turning head device (configured as a hold-down device 16) and are provided for fixing the module on the first support strip 1 by joining the microchip module that has been placed on the first support strip 1 with a predefined depth of penetration. The displacement movement brought about by an acceleration pulse is indicated by the arrow 15. During the assembly operation, the tools work against a hold-up device in the form of an anvil, said hold-up device being fixed in its position.

During the operation of joining the chip modules, the tools hook into the joining partners and are moved into their original position within the turning head device 9 by means of a restoring device.

In order to rotate the turning head and to transport the first support strip 1, it is necessary to release the corresponding components. To this end, the hold-up device (anvil) is lowered downward and an index guide device for the second support strip is raised upward.

An index guide device ensures precise positioning of the support strips 5a, 5b in the lateral direction and in the direction of advance with respect to the cutting device 10. Here, in order to synchronize the advance movement of the first and second support strips 1, 5a, 5b and the movement of the cutting device, a step-by-step advance movement is carried out by means of a control device (not shown here).

FIG. 3 shows, in a schematic side view, part of the apparatus according to the invention with the turning head device according to one embodiment of the invention. The turning head device 9 consists of a total of two turning head sides 9a and 9b. Accordingly, upon each transfer operation of a microchip module, the turning head rotates through 180° in order to transfer the microchip module 12 from the upper, second support strip 5 to the lower, first support strip 1 by means of a vacuum which exerts a suction. To do this, the turning head rotates about the axis of rotation 9c.

As soon as the microchip module 12 is located just above the first support strip 1 as a result of rotating the turning head, a striking device 19 with an integrated hammer is pivoted (as indicated by the arrow 21) by means of the force pulse (as indicated by the arrow 20) which is triggered by an electromagnetic drive (not shown here). This pivoting causes a tool 22 to move downward, as a result of which a joining tool 23, which is fitted on the hold-down device 16, is pressed against the support strip 1 and a clinching operation takes place. The anvil 24 represents a suitable opposing piece during the joining operation.

The restoring device 25 then returns the tool 22 to the starting position by virtue of an upward movement.

A vacuum suction plate (not shown in any greater detail) for exerting suction on the module is fixed to the hold-down device 16.

All the devices for separating and assembling the chip modules and also the striking device can be adjusted and displaced above the first support strip 1 transversely to the transport direction of the strip, and can be positioned by means of control elements.

FIG. 4 shows, in a schematic side view, a cutting device 10 according to one embodiment of the invention, of which the blade holder 26 with blades 27 for cutting the individual microchip modules 12 out of the second support strip 5 can be displaced in the direction of the arrows 29 and 30. To this end, the cutting device 10 has at least two blades 27 for cutting out the modules 12, said blades being guided by a guide web 28. The arrow 29 indicates the cutting direction and the arrow 30 indicates the blade stroke.

FIG. 5 shows, in a schematic plan view, an index guide device 31 for guiding the second strip 5 in a lateral and forward direction. To this end, the index guide device 31 has two guide rails 32 and slides 33 which can be displaced thereon for the advance movement of the strip 5, as shown by the arrows 34. There are also slides 35 for transverse displacement, as shown by the arrows 36.

The electromagnetic drive device 14 (shown in FIG. 6) for the striking device acts by means of a sliding movement on the assembly tools with its front part 14a which is designed as a striker pin, said assembly tools being required to clinch the microchip modules onto the first support strip 1. The striker pin 14a is connected to an adjustment device for adjusting the magnetic force, said adjustment device essentially consisting of a base frame 38, two clamping wedges 39 and a spiral spring 40. The magnetic force is generated by a magnet 37.

All the features disclosed in the application documents are claimed as essential to the invention since, individually or in combination, they are novel with respect to the prior art.

### LIST OF REFERENCES

1 first support strip
2, 6 first rolls
3, 7 second rolls
4, 8 strip running directions
5, 5a, 5b second support strip
9, 9a, 9b turning head device
10 cutting device
10a displacement direction of the cutting device
11 rotational movement of the turning head device
12 microchip modules
13 camera
14 electromagnetic drive device
14a front part of the electromagnetic drive device
15 displacement direction of the drive device
16 hold-down device
17 displacement directions of the index guide device
18 antennas
19 striking device
20 force pulse
21 pivoting direction
22 tool
23 joining tool
24 anvil
25 restoring device
26 blade holder
27 blade
28 guide web
29 cutting direction
30 blade stroke
31 index guide device
32 guide rails
33, 35 slides
34, 36 slide displacement
37 magnet
38 base frame
39 clamping wedges
40 spiral springs

1. (canceled)

2. The apparatus as claimed in claim 14, further comprising:
a vacuum-generating device connected to the turning head device for exerting suction on at least one microchip module (12) which is detached from the second support strip.

3. The apparatus as claimed in claim 14, wherein the turning head device (9) can be rotated through 180° or 90°.

4. The apparatus as claimed in claim 14, further comprising:
at least one assembly tool (22, 23) which is arranged on the first support (1) for pressing, the microchip module (12) at a predefined location on the first support (1) relative to the antennas (18).

5. The apparatus as claimed in claim 4, wherein the assembly tool (22) includes an electromagnetic drive device (14) for moving the assembly tool and for carrying out the pressing operation with a predefined depth of penetration of the microchip modules (12) into the first support (1), wherein the drive device (14) includes an adjustment device (38, 39, 40) for setting a predefinable force at which activation of the drive device (14) takes place.

6. The apparatus as claimed in claim 14, further comprising:
a separating device (10) for separating the microchip modules (12) from the second support (5, 5a, 5b).

7. The apparatus as claimed in claim 6, wherein the separating device (10) includes cutting device which comprises at least one blade element (27).

8. The apparatus as claimed in claim 6, further comprising:
a control device for moving the assembly tool as a function of the current positions of the separating device (10), the turning head device (9) and the microchip modules (12) which are to be pressed on.

9. The apparatus as claimed in claims 6, further comprising:
an index guide device (31) for guiding the second support (5, 5a, 5b) in at least two directions, in order to carry out precise positioning of individual microchip modules (12) with respect to the separating device (10) and the turning head device (9).

10. The apparatus as claimed in claim 14, wherein the supports (1; 5, 5a, 5b), are unwound from first rolls (2, 6) and wound onto second rolls (3, 7).

11. A method forjoining microchip modules to antennas (18) which are arranged on at least one first support (1) for producing transponders, the method comprising:
detaching the microchip modules (12) from at least one second support (5, 5a, 5b); and
applying the detached microchip modules to predefined locations on the first support (1), wherein the two supports run parallel to one another at a predefined section, and the microchip modules are applied to the locations by means of a turning head device (9) which can rotate between the supports (1: 5, 5a, 5b) about an axis that is perpendicular to a normal to surfaces of the supports.

12. The method as claimed in claim 11, wherein applying includes exerting suction on at least one microchip module (12) which has previously been detached from the second support (5, 5a, 5b) and rotationally moving the microchip module to place it at the predefined location on the first support (1).

13. The method as claimed in claim 12 further comprising:
separating individual microchip modules (12) from the second support (5, 5a, 5b); and pressing the separated microchip modules (12) onto the first support (1), wherein separating and pressing are performed simultaneously.

14. An apparatus for joining microchip modules to antennas, the apparatus comprising:
at least one first support for transferring one or more antennas;
at least one second support for transferring the microchip modules, wherein these supports are arranged parallel to one another at a predefined section; and
a turning head device for transferring one or more of the microchip modules from the second support to the first support by way of a rotational movement, wherein the turning head device rotates about an axis that is approximately perpendicular to a normal of surfaces of the first and second support.

15. The apparatus as claimed in claim 14 further comprising:
an electrostatic attraction device for electrostatically removing at least one microchip module that has been detached from the second support strip.
